(19) United States
(12) Patent Application Publication
(10) Pub. No.: US 2007/0004112 A1
(43) Pub. Date: Jan. 4, 2007

(54) METHOD OF FORMING THIN FILM TRANSISTOR AND METHOD OF REPAIRING DEFECTS IN POLYSILICON LAYER

(76) Inventors: Chia-Nan Shen, Taipei County (TW); Cheng-Nan Hsieh, Taichung County (TW); Hsi-Ming Chang, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,210

(22) Filed: Jul. 27, 2005

(30) Foreign Application Priority Data
Jun. 30, 2005 (TW) 94122080

(51) Int. Cl. H01L 21/8234

(52) U.S. Cl. 438/197

(57) ABSTRACT

A method of forming a thin film transistor is described. A polysilicon layer is formed over a substrate, wherein the polysilicon layer has a first region, a second region and a channel region between the first and second regions. A nitrogen doping process is carried out to dope nitrogen into the polysilicin layer. A gate insulating layer and a gate are sequentially formed over the polysilicon layer, wherein the gate is formed over the channel region. A doping process is performed so as to form a source and a drain in the first region and second region, respectively.

### CROSS-REFERENCE TO RELATED APPLICATION

This application claims the priority benefit of Taiwan application serial no. 94122080, filed Jun. 30, 2005. All disclosure of the Taiwan application is incorporated herein by reference.

### BACKGROUND OF THE INVENTION

1. Field of the Invention

The present invention generally relates to a method of forming a thin film transistor (TFT). More particularly, the present invention relates to a method of forming a low temperature polysilicon thin film transistor (LTPS-TFT) and a method of repairing defects in a polysilicon layer.

2. Description of Related Art

Thin film transistors are divided into amorphous silicon thin film transistors and polysilicon thin film transistors in accordance with their channel material. The polysilicon thin film transistor has properties of smaller power consuming and higher electron mobility comparing with the amorphous silicon thin film transistor so that it has been valued.

FIG. 1A˜FIG. 1D are cross-section views showing a conventional method of forming a thin film transistor. As shown in FIG. 1A, an amorphous silicon layer 102 is formed over a substrate 100. A laser or thermal annealing process is performed so that the amorphous silicon layer 102 is melted and re-crystallized to form a polysilicon layer 102a as shown in FIG. 1B. In FIG. 1B, a gate insulating layer 104 and a gate 106 are sequentially formed over the polysilicon layer 102a. Next, a source 108 and a drain 110 are formed in the polysilicon layer 102a beside the gate 106 by implantation process using the gate 106 as mask so that a TFT 120 is formed (FIG. 1D), wherein the region in the polysilicon layer 102a under the gate 106 is a channel region 112.

In the TFT 120 of FIG. 1D, the polysilicon layer 102a has grains having different grain orientations and grain boundaries therein. Usually, there are several defects, such as broken bond defects, at the grain boundaries. These defects may trap carriers moving between the source and the drain so that the carrier mobility in the channel region 112 is reduced.

In order to resolve the above problem, hydrogen is doped into the polysilicon layer in the prior art. Because covalent bonds are formed between the hydrogen atoms and the silicon so that the defects can be eliminated and the carrier mobility can be improved. However, Si—H bond has lower bonding energy so that it is broken easily. Hence, the number of Si—H bonds formed in the polysilicn layer may be reduced as the TFT is operated, and the number of the carriers trapped by the defects may be increased.

In addition, in the conventional TFT processes, a silicon oxide layer is usually as the gate insulating layer 104. However, oxygen and impurities may diffuse into the polysilicon layer 102a during forming the gate insulating layer 104 so that the channel resistance is increased and the drain current is reduced. In addition, if the impurities are existed between the polysilicon layer 102a and the gate insulating layer 104, the TFT threshold voltage is reduced and the device stability is deteriorated.

### SUMMARY OF THE INVENTION

Accordingly, the present invention is directed to a method of forming a thin film transistor capable of preventing oxygen and impurities from diffusing into the channel region so as to improve TFT stability and performance.

The present invention is directed to a method of repairing defects in a polysilicon layer capable of repairing defects in the polysilicon layer and forming Si—N bonds to reduce the polysilicon layer resistance.

A method of forming a thin film transistor is provided. A polysilicon layer is formed over a substrate, wherein the polysilicon layer has a first region, a second region and a channel region between the first and second regions. A nitrogen doping process is carried out to dope nitrogen into the polysilicin layer. A gate insulating layer and a gate are sequentially formed over the polysilicon layer, wherein the gate is formed over the channel region. A doping process is performed so as to form a source and a drain in the first region and second region, respectively.

According to an embodiment of the present invention, the step of forming the polysilicon layer comprises forming an amorphous silicon layer over the substrate; and performing an annealing process so that the amorphous silicon layer is melted and re-crystallized to form the polysilicon layer. The annealing process comprises a laser annealing process or a thermal annealing process. The laser annealing process comprises an excimer laser annealing process, for example.

According to an embodiment of the present invention, before forming the amorphous silicon layer, a buffer layer is formed over the substrate.

According to an embodiment of the present invention, after forming the amorphous silicon layer and before performing the annealing process, a dehydrogenation treatment is performed to the amorphous silicon layer.

According to an embodiment of the present invention, before performing the nitrogen doping process, a sacrificial layer is formed over the polysilicon layer. After the nitrogen doping process is performed and before the gate insulating layer is formed, the sacrificial layer is removed. The sacrificial layer has a material comprising silicon oxide, for example.

According to an embodiment of the present invention, after performing the nitrogen doping process and before removing the sacrificial layer, an activation process is performed to the polysilicon layer.

According to an embodiment of the present invention, the nitrogen doping process comprises a nitrogen ion (N+) implantation process or a nitrogen gas ion (N₂+) implantation process.

According to an embodiment of the present invention, after forming the source and the drain, the method further comprises forming a dielectric layer over the polysilicon layer to cover the gate, wherein the dielectric layer has a plurality of contact holes therein, and the contact holes pass through the gate insulating layer and expose the source and the drain; and forming a source conductive layer and a drain conductive layer over the dielectric layer, and the source conductive layer and the drain conductive layer are electrically connected with the source and the drain, respectively, through the contact holes in the dielectric layer.

A method of repairing a polysilicon layer is also provided. An amorphous silicon layer is formed over the substrate. An annealing process is performed so that the amorphous silicon layer is melted and re-crystallized to form a polysilicon layer. A nitrogen doping process is performed to dope nitrogen into the polysilicin layer.

According to an embodiment of the present invention, before forming the amorphous silicon layer, a buffer layer is formed over the substrate.

According to an embodiment of the present invention, said annealing process comprises a laser annealing process or a thermal annealing process. The laser annealing process comprises an excimer laser annealing process, for example.

According to an embodiment of the present invention, after forming the amorphous silicon layer and before performing the annealing process, a dehydrogenation treatment is performed to the amorphous silicon layer.

According to an embodiment of the present invention, before performing the nitrogen doping process, a sacrificial layer is formed over the polysilicon layer. The sacrificial layer has a material comprising silicon oxide, for example. In addition, after the nitrogen doping process is performed, the sacrificial layer is removed.

According to an embodiment of the present invention, after performing the nitrogen doping process and before removing the sacrificial layer, an activation process is performed to the polysilicon layer.

According to an embodiment of the present invention, the nitrogen doping process comprises a nitrogen ion (N+) implantation process or a nitrogen gas ion (N₂+) implantation process.

In the present invention, nitrogen is doped into the polysilicon layer to form Si—N bonds so as to repair the defects in the polysilicon layer. If the repairing method is applied to the TFT process, the carrier mobility in the channel region can be improved and oxygen and impurities do not diffuse into the polysilicon layer during forming the gate insulating layer. Thus, threshold voltage shift of the TFT can be reduced and the device stability can be improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A˜FIG. 1D are cross-section views showing a conventional method of forming a thin film transistor.

FIG. 2 is a flow chart showing a method of forming a thin film transistor according to an embodiment of the present invention.

FIG. 3A˜FIG. 3F are cross-section views showing a method of forming a thin film transistor according to an embodiment of the present invention.

FIG. 4 is a flow chart showing a method of forming a polysilicon layer according to an embodiment of the present invention.

FIG. 5A˜FIG. 5B are cross-section views showing a method of forming a polysilicon layer of FIG. 3A according to an embodiment of the present invention.

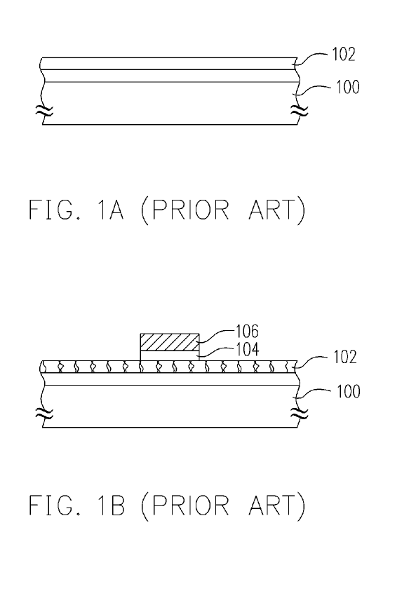

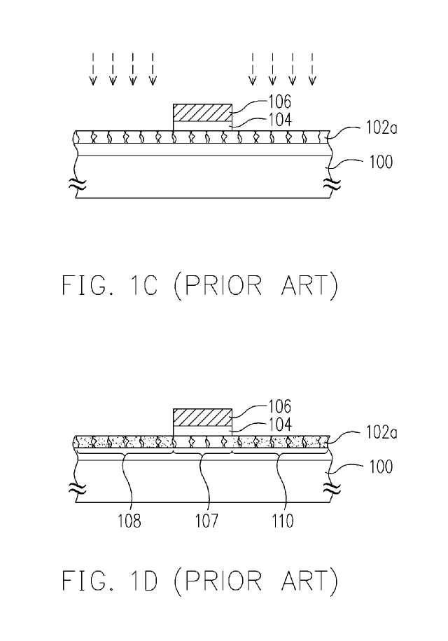

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In the present invention, nitrogen is doped into a polysilicon layer so as to repair defects in the polysilicon layer. If the repairing method is applied to the TFT fabricating process, the TFT device stability and performance can be improved. The TFT fabricating process combined with the repairing method of the polysilicon layer is described as follows. However, the repairing method of the polysilicon layer is not limited in the TFT fabricating process. The repairing method can also be applied to other device processes comprising forming a polysilicon layer.

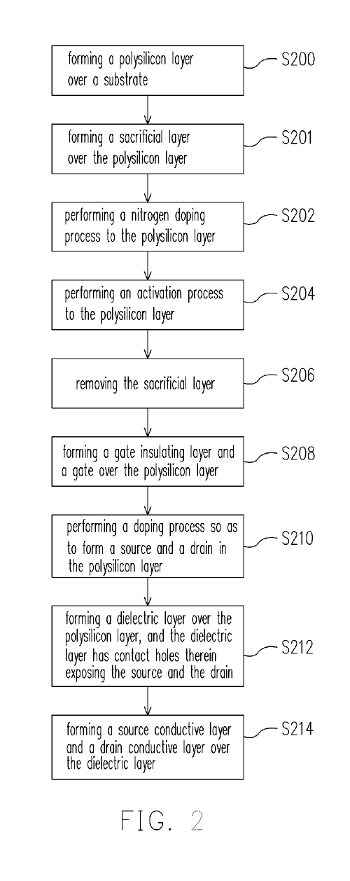

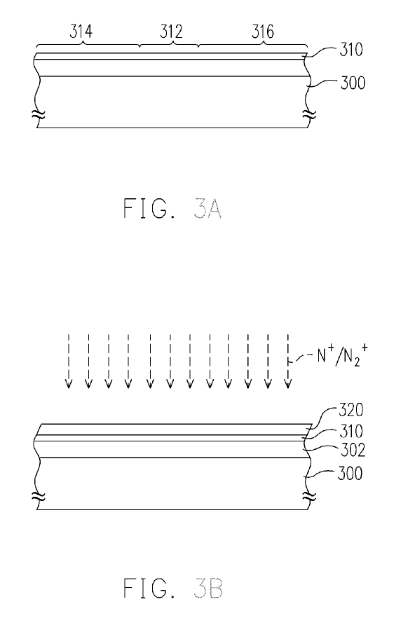

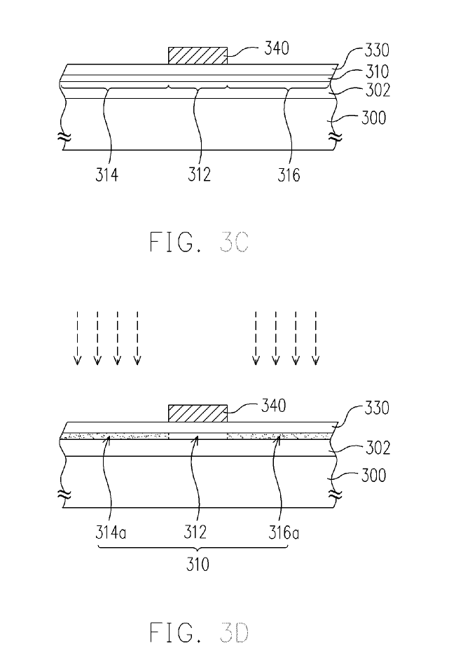

FIG. 2 is a flow chart showing a method of forming a thin film transistor according to an embodiment of the present invention. FIG. 3A˜FIG. 3F are cross-section views showing a method of forming a thin film transistor according to an embodiment of the present invention. As shown in FIG. 2 and FIG. 3A, a polysilicon layer 310 is formed over a substrate 300 (S200). The polysilicon layer 310 comprises a channel region 312, a first region 314 and a second region 316, and the channel region 312 is between the first region 314 and the second region 316.

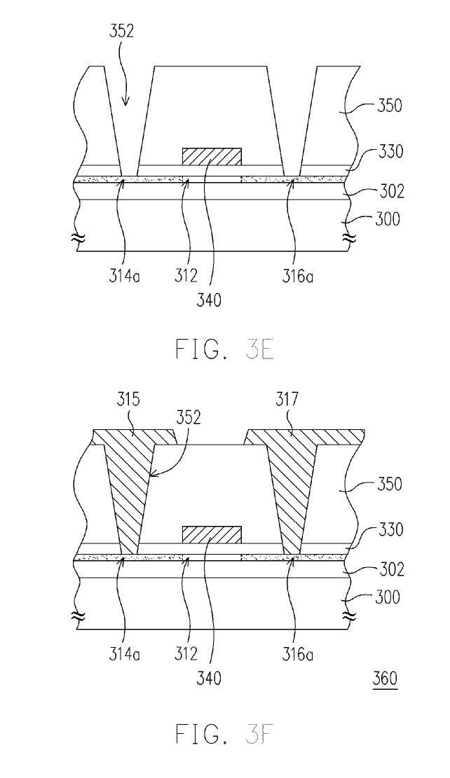

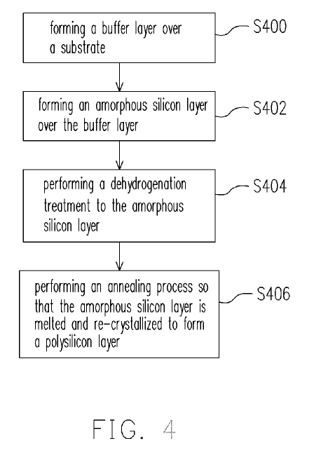

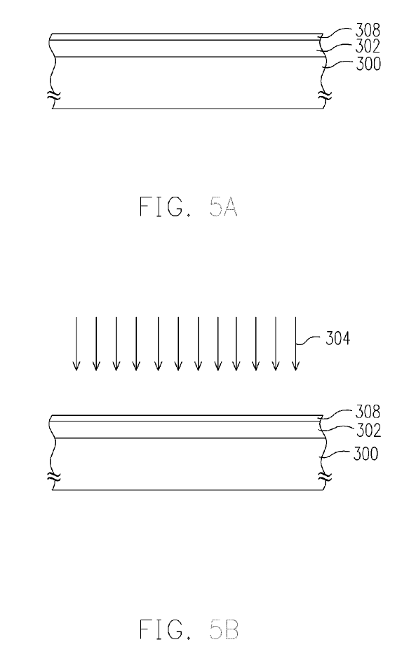

In an embodiment, the polysilicon layer 310 is formed, for example, by melting and re-crystallizing an amorphous silicon layer, as shown in FIG. 4 that is a flow chart showing a method of forming a polysilicon layer 310 of FIG. 3A. FIG. 5A˜FIG. 5B are cross-section views showing a method of forming a polysilicon layer of FIG. 3A. As shown in FIG. 4 and FIG. 5A, an amorphous silicon layer 308 having a thickness about 500 angstrom is formed over a substrate 300 (S402). In an embodiment, before forming the amorphous layer 308, a buffer layer 302 is formed over the substrate 300 (S400) so as to prevent impurities in the substrate 300 from diffusing into the amorphous silicon layer 308 during subsequent processes. The buffer layer 302 has a thickness of about 3000 angstrom and has a material comprising silicon oxide, silicon nitride or other insulating material. The buffer layer 302 can be formed by plasma enhanced chemical vapour deposition process.

As shown in FIG. 4 and FIG. 5B, after forming the amorphous layer 308, a dehydrogenation treatment to the amorphous silicon layer 308 is carried out (S404). Thereafter, an annealing process, such as a laser annealing process or a thermal annealing process, is performed (S406) so that the amorphous silicon layer 308 is melted and re-crystallized to form a polysilicon layer 310 (as shown in FIG. 3A). In an embodiment, the annealing process is performed with excimer laser beams 304, and that is so-called excimer laser annealing process. The energy of the laser annealing process is from 250 mJ/cm²to 300 mJ/cm², for example, and preferably is at about 260 mJ/cm².

It should be noted that the polysilicon layer 310 formed by ELA process has grains having defects at the grain boundaries. The following method is used to repair the defects.

As shown in FIGS. 2, 3B, a nitrogen doping process (S202) is performed after forming the polysilicon layer 310 shown in FIG. 4. In an embodiment, before the nitrogen doping process, a sacrificial layer 320 is formed over the polysilicon layer 310 (S201) so as to prevent the surface of the polysilicon layer 310 from damaging during the subsequent nitrogen doping process. The sacrificial layer 320 has a material comprising silicon oxide, for example, and be formed by chemical vapor deposition process, for example.

As shown in FIG. 3B, the nitrogen doping process is, for example, an ion implantation process, and nitrogen ions (N+) or nitrogen gas ions (N₂+) are implanted into the polysilicon layer 310 such that Si—N bonds are formed in the polysilicon layer 310. In the case, the ion implantation process has an implanting energy from 5 KeV to 100 KeV and has a dosage from 10¹³ ion/cm² to 2*10¹⁵ ion/cm². Thereafter, another ion implantation process of phosphorous, arsenic or boron for adjusting the TFT threshold voltage may be carried out, if necessary.

As shown in FIG. 2, after the nitrogen doping process, an activation process (S204) is performed to the polysilicon layer 310 shown in FIG. 3B so that dopants in the polysilicon layer 310 are activated and diffusing. The activation process is, for example, a furnace thermal process or a rapid thermal process. If the activation process is performed by the furnace thermal process, the polysilicon layer 310 is activated at 450° C.˜550° C. about 2 hours to 4 hours. When the activation process is performed by the rapid thermal process, the polysilicon layer 310 is activated at 550° C.˜650° C. about 10 seconds to 3 minutes.

In particular, the sacrificial layer 320 formed in the step S201 not only protects the polysilicon layer 310 from damaging during ion implantation processes but also prevents nitrogen in the polysilicon layer from diffusing out of the polysilicon layer when the activation process is conducted. After the activation process is performed, the sacrificial layer 320 is removed (S206). The sacrificial layer 320 is removed by etching process, for example.

It should be noted that nitrogen doped in the polysilicon layer 310 has a distribution of that the nitrogen concentration is decreased from the top portion to the bottom portion of the polysilicon layer 310, wherein the bottom portion is near the substrate 300 while the top portion is distant from the substrate 300. In the other word, the polysilicon layer 310 has the highest nitrogen concentration on its top surface.

As shown in FIG. 2 and FIG. 3C, after the steps of forming the polysilicon layer and repairing the polysilicon layer, a gate insulating layer 330 and a gate 340 are sequentially formed over the polysilicon layer 310 (S208), wherein the gate 340 is formed over the channel region 312. The gate insulating layer 330 and a gate 340 are formed by forming an insulating layer and a metal layer (not shown) over the polysilicon layer 310, and then patterning the metal layer to form the gate 340 with a photolithography and etching process.

In an embodiment, the gate insulating layer 330 has a material comprising silicon oxide. When forming the silicon oxide layer 330, Si—N bonds on the surface of the polysilicon layer 310 can prevent oxygen and impurities from diffusing into the polysilicon layer 310 so that the polysilicon layer 310 resistance can be reduced.

Thereafter, a doping process is performed to the first and second regions 314, 316, as shown in FIG. 3D so that a source 314a and a drain 316a is formed beside the channel region 312. The doping process is an ion implantation process using the gate 340 as mask. In another embodiment, a lightly implantation process may further be performed to form lightly doped regions (not shown) besides the channel regions 312 before forming the source 314a and the drain 316a, if necessary.

After the structure of TFT in FIG. 3D is formed, metal conductive layers electrically connected with the source 314a and the drain 316a are formed. As shown in FIG. 2 and FIG. 3E, a dielectric layer 350 is formed over the polysilicon layer 310 to cover the gate 340, wherein the dielectric layer 350 has several contact holes 352 passing through the gate insulating layer 330 to expose the source 314a and the drain 316a in the polysilicon layer 310. Thereafter, a source conductive layer 315 and a drain conductive layer 317 are formed over the dielectric layer 350 (S214), as shown in FIG. 3F, such that a LPTS-TFT 330 is formed. The source conductive layer 315 and the drain conductive layer 317 are filled into the contact holes 352 and electrically connected with the source 314a and the drain 316a.

In an embodiment, a data line (not shown) electrically connected the source conductive layer 315 can be defined when forming the source and drain conductive layers 315, 317 so as to simplify the fabricating process.

As above mentioned, nitrogen is doped into the polysilicon layer to form Si—N bonds in the polysilicon layer to repair the defects. In addition, if the repairing method is applied to the TFT process, the defects in the polysilicon channel region can be reduced so as to improve the carrier mobility in the channel region. It may also prevent oxygen and impurities from diffusing into the polysilicon layer during forming the gate insulating layer. Therefore, the TFT threshold voltage shift can be reduced and the device stability can be improved.

In particular, Si—N bond is stronger that Si—H bond so that the channel region having Si—N bonds therein has a better tolerance for the hot electron impact from short channel effect. Hence, the TFT fabricated by the method of the present invention has good device performance.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a thin film transistor, comprising:
forming a polysilicon layer over a substrate, wherein the polysilicon layer has a first region, a second region and a channel region between the first and second regions;
performing a nitrogen doping process to dope nitrogen into the polysilicin layer;
sequentially forming a gate insulating layer and a gate over the polysilicon layer, wherein the gate is formed over the channel region; and
performing a doping process so as to form a source and a drain in the first region and second region, respectively.

2. The method according to claim 1, wherein the step of forming the polysilicon layer comprises:
forming an amorphous silicon layer over the substrate; and
performing an annealing process so that the amorphous silicon layer is melted and re-crystallized to form the polysilicon layer.

3. The method according to claim 2, wherein the annealing process comprises a laser annealing process or a thermal annealing process.

4. The method according to claim 3, wherein the laser annealing process comprises an excimer laser annealing process.

5. The method according to claim 2, further comprising forming a buffer layer over the substrate before forming the amorphous silicon layer.

6. The method according to claim 2, further comprising performing a dehydrogenation treatment to the amorphous silicon layer after forming the amorphous silicon layer and before performing the annealing process.

7. The method according to claim 1, further comprising:
forming a sacrificial layer over the polysilicon layer before performing the nitrogen doping process; and
removing the sacrificial layer after performing the nitrogen doping process and before forming the gate insulating layer.

8. The method according to claim 7, further comprising performing an activation process to the polysilicon layer after performing the nitrogen doping process and before removing the sacrificial layer.

9. The method according to claim 7, wherein the sacrificial layer has a material comprising silicon oxide.

10. The method according to claim 1, wherein the nitrogen doping process comprises a nitrogen ion (N+) implantation process or a nitrogen gas ion (N₂+) implantation process.

11. The method according to claim 1, wherein after forming the source and the drain, the method further comprises:
forming a dielectric layer over the polysilicon layer to cover the gate, wherein the dielectric layer has a plurality of contact holes therein, and the contact holes pass through the gate insulating layer and expose the source and the drain; and
forming a source conductive layer and a drain conductive layer over the dielectric layer, and the source conductive layer and the drain conductive layer are electrically connected with the source and the drain, respectively, through the contact holes in the dielectric layer.

12. A method of repairing a polysilicon layer, comprising:
forming an amorphous silicon layer over the substrate;
performing an annealing process so that the amorphous silicon layer is melted and re-crystallized to form a polysilicon layer; and
performing a nitrogen doping process to dope nitrogen into the polysilicin layer.

13. The method according to claim 12, further comprising forming a buffer layer over the substrate before forming the amorphous silicon layer.

14. The method according to claim 12, further comprising performing a dehydrogenation treatment to the amorphous silicon layer after forming the amorphous silicon layer and before performing the annealing process.

15. The method according to claim 12, wherein the annealing process comprises a laser annealing process or a thermal annealing process.

16. The method according to claim 15, wherein the laser annealing process comprises an excimer laser annealing process.

17. The method according to claim 12, further comprising forming a sacrificial layer over the polysilicon layer before performing the nitrogen doping process.

18. The method according to claim 17, wherein the sacrificial layer has a material comprising silicon oxide.

19. The method according to claim 17, further comprising removing the sacrificial layer after performing the nitrogen doping process.

20. The method according to claim 19, further comprising performing an activation process to the polysilicon layer after performing the nitrogen doping process and before removing the sacrificial layer.

21. The method according to claim 12, wherein the nitrogen doping process comprises a nitrogen ion (N+) implantation process or a nitrogen gas ion (N₂+) implantation process.
